(19) United States
(12) Patent Application Publication
(10) Pub. No.: US 2015/0111375 A1
(43) Pub. Date: Apr. 23, 2015

(54) Wafer Level Chip Scale Package Device with One or More Pre-solder Layers and Manufacturing Method Thereof

(71) Applicant: Po-Jui Chen, Taipei (TW)

(72) Inventor: Po-Jui Chen, Taipei (TW)

(73) Assignee: RICHTEK TECHNOLOGY CORPORATION, Chupei City (TW)

(21) Appl. No.: 14/579,753

(22) Filed: Dec. 22, 2014

Related U.S. Application Data
(62) Division of application No. 13/569,729, filed on Aug. 8, 2012.

(51) Int. Cl. H01L 23/00

(52) U.S. Cl. CPC H01L 24/11; H01L 2924/0105; H01L 2924/01029; H01L 2924/01047; H01L 2924/0132; H01L 2924/0133; H01L 2224/13007; H01L 2924/014
USPC 438/614

(57) ABSTRACT

The present invention discloses a method for manufacturing a wafer level chip scale package device with one or more pre-solder layers, and a wafer level chip scale package device made thereby. The device includes: a chip including at least one bonding pad; a UBM layer disposed on the bonding pad; at least one pre-solder layer disposed on the UBM layer; and a bump melted and combined with the pre-solder layer. The device may include two pre-solder layers.

### CROSS REFERENCE

The present invention claims priority to TW 100137821, filed on Oct. 19, 2011. The present application is a divisional application of U.S. Ser. No. 13/569,729, filed on Aug. 8, 2012.

### BACKGROUND OF THE INVENTION

1. Field of Invention

The present invention relates to a wafer level scale package (WLCSP) device and a manufacturing method, in particular to such a package device having I/O contacts with larger stand-off heights and sizes. Thus, the reliability of the package device is improved.

2. Description of Related Art

Wafer level scale package is a technology which utilizes a ball mounting process to form the external I/O contacts of a chip. According to Coffin-Mansion formula, among various factors to affect the fatigue failure from temperature cycling, the stand-off height of the ball is one factor wherein the higher the standoff height is, the better the endurance cycle is. Therefore, the prior art puts forth some methods for increasing the stand-off heights of the mounted balls of the I/O contacts. In this regard, using the solder balls with a larger diameter is the most straightforward way to increase the stand-off heights of the mounted balls. However, if the ball-to-ball pitch between the balls is maintained the same while the ball size is increased, the adjacent solder balls are easily melted together with one another, or a position shift often occurs during a successive reflow process to result in short-circuit. In other words, if the ball pitch of the chip is limited, the stand-off height of a single solder ball is also limited.

FIG. 1 is a schematic diagram illustrating the assembly of a PCB and a conventional WLCSP device. Referring to FIG. 1, each I/O contact 12 of the WLCSP device 10 includes two solder balls which are stacked on an active surface of the chip 13. The stand-off height is accordingly increased due to the stack of two solder balls. The epoxy resin 14 surrounds the base solder balls which are directly mounted on the chip 13 to protect them from damages. The second solder balls can be mounted in the openings of the epoxy resin 14 exposing the base solder balls, so the I/O contacts 12 are formed by stacked balls. The second solder balls stacked on the base solder balls are soldered to the PCB 11. Because the coefficients of thermal expansion (CTEs) of the chip 13 and the PCB 11 are very different and the different CTEs cause the materials to have different deformation, the two ends of the I/O contacts 12 have different displacements to cause stress. In particular, if the size of the chip 13 is relatively large, the I/O contacts 12 closer to the corners of the chip 13 will receive a higher stress. Although such I/O contacts 12 having a larger stand-off height H (H being the distance between the surface of the chip 13 and the PCB 11) can improve the reliability of the package device and the epoxy resin 14 can act as a stress buffer layer to somewhat relieve the stress, it requires twice solder ball formation processes to manufacture the WLCSP device 10 and special epoxy resin. Thus, the overall process is complicated and the cost is high. Furthermore, this prior art has stress and misalignment problems which are not ignorable.

FIG. 2 shows a schematic diagram of a WLCSP device disclosed by U.S. Pat. No. 6,930,032. A plurality of bonding pads 203 are around the chip 201, and each of them is connected to a redistribution bonding pad 205 through a redistribution layer (RDL). The buffer layer 211 is formed on the redistribution bonding pad 205, and the concave-shaped UBM (under bump metallurgy) layer 215 is deposited on the buffer layer 211. The solder balls 217 are soldered to the UBM layer 215, so the weak necks of the solder balls 217 can be protected by the special concave-shaped structure. There are two dielectric layers 207 and 209 between the concave-shaped bodies. Though the special design of the UBM layer 215 can protect the weak necks of the solder balls 217 from cracking, manufacturing the device needs modified photo masks and special process parameters. Thus, the manufacturing process is complicated and the cost is higher.

In view of above, the present invention overcomes the foregoing drawbacks by providing a wafer level scale package (WLCSP) device and a manufacturing method, wherein the stand-off heights of the I/O contacts of the package device are increased, and hence the reliability of the package device is improved.

### SUMMARY OF THE INVENTION

An objective of the present invention is to provide a wafer level scale package device.

An objective of the present invention is to provide a method for manufacturing a wafer level scale package device.

To achieve the foregoing objectives, in one aspect, the present invention provides a wafer level chip scale package device. The device comprises: a chip including at least one bonding pad; a UBM layer disposed on the bonding pad; a pre-solder layer disposed on the UBM layer; and a bump melted and combined with the pre-solder layer.

In one embodiment, the foregoing WLCSP device comprises: a barrier layer disposed on the bonding pad; and a seed layer disposed between the barrier layer and the UBM layer.

In one embodiment, the bump is a solder ball. The material of the pre-solder layer includes a metal or an alloy, wherein the metal or alloy is capable of being melted and combined with the bump.

In one embodiment, the material of the pre-solder layer includes a metal or an alloy, wherein the metal or alloy is capable of being melted and combined with the bump.

In one embodiment, the pre-solder layer and the bump are combined together to form an I/O contact. The size of the I/O contact is larger than the size of the bump.

In yet another aspect, the present invention provides a WLCSP package device. The device comprises: a chip including at least one bonding pad; a UBM layer disposed on the bonding pad; a first pre-solder layer disposed on the UBM layer; a second pre-solder layer disposed on the first pre-solder layer, wherein the melting point of the first pre-solder layer is higher than the melting point of the second pre-solder layer; and a bump melted and combined with the second pre-solder layer.

In one embodiment, the material of the first pre-solder layer is solder with a higher melting point.

In another embodiment, the present invention provides a method for manufacturing a WLCSP device. The method comprises: providing a chip having at least one bonding pad; forming a UBM layer on the bonding pad; forming a pre-solder layer on the UBM layer; and melting and combining a bump and the pre-solder layer.

In one embodiment, the method comprises: forming a high melting point pre-solder layer between the UBM layer and the pre-solder layer, wherein the melting point of the high melting point pre-solder layer is higher than the melting point of the pre-solder layer.

In one embodiment, the method comprises: forming a barrier layer on the bonding pad; and forming a seed layer between the barrier layer and the UBM layer.

The objectives, technical details, features, and effects of the present invention will be better understood with regard to the detailed description of the embodiments below, with reference to the drawings.

### BRIEF DESCRIPTION OF THE DRAWINGS

FIG. 1 is a schematic diagram illustrating the assembly of a PCB and a conventional WLCSP device.

FIG. 2 shows a schematic diagram of a prior art WLCSP device.

FIGS. 3A-3I show schematic diagrams of an embodiment of the present invention, illustrating the manufacturing steps of a WLCSP device.

FIGS. 4A-4D show schematic diagrams of another embodiment of the present invention, illustrating the manufacturing steps of a WLCSP device.

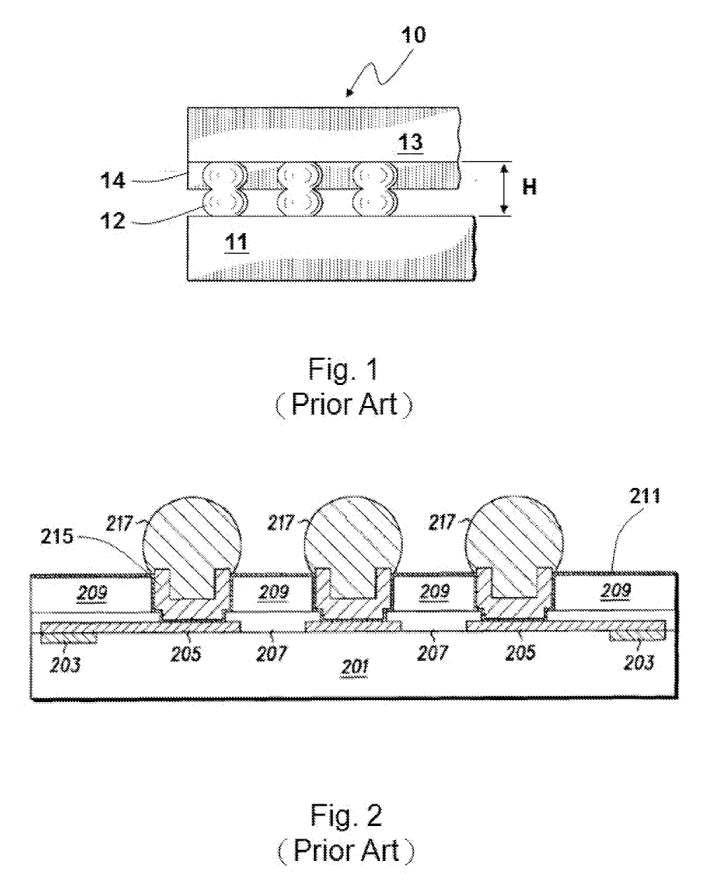

### DESCRIPTION OF THE PREFERRED EMBODIMENTS

The drawings as referred to throughout the description of the present invention are for illustration only, to show the interrelationships between the process steps and between the layers of a WLCSP device, but not drawn according to actual scale.

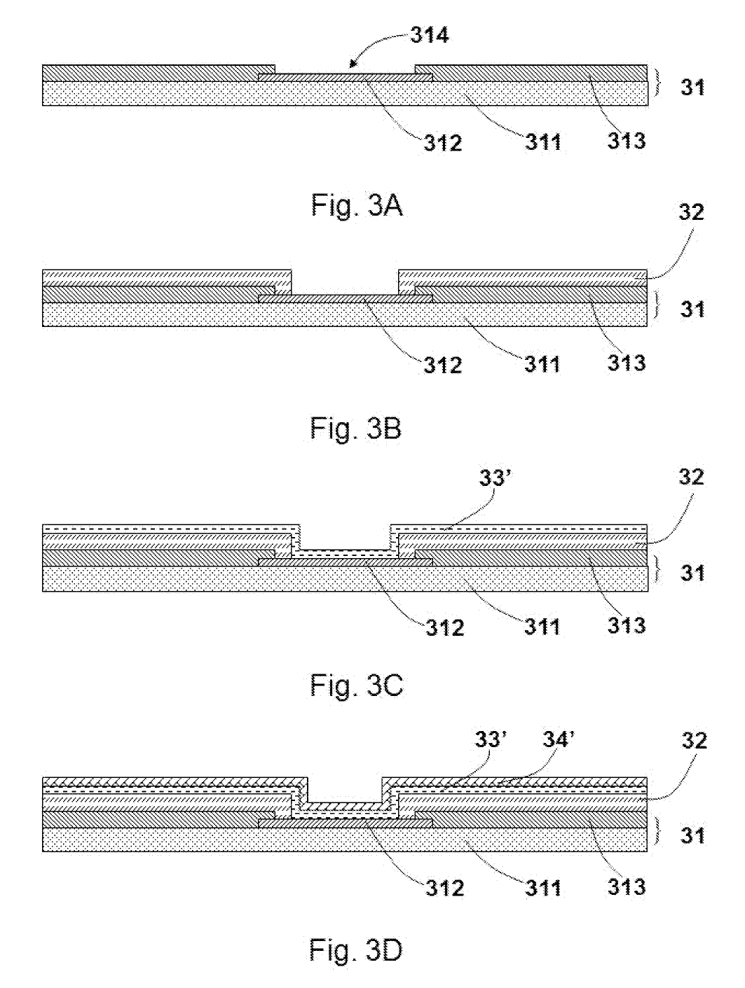

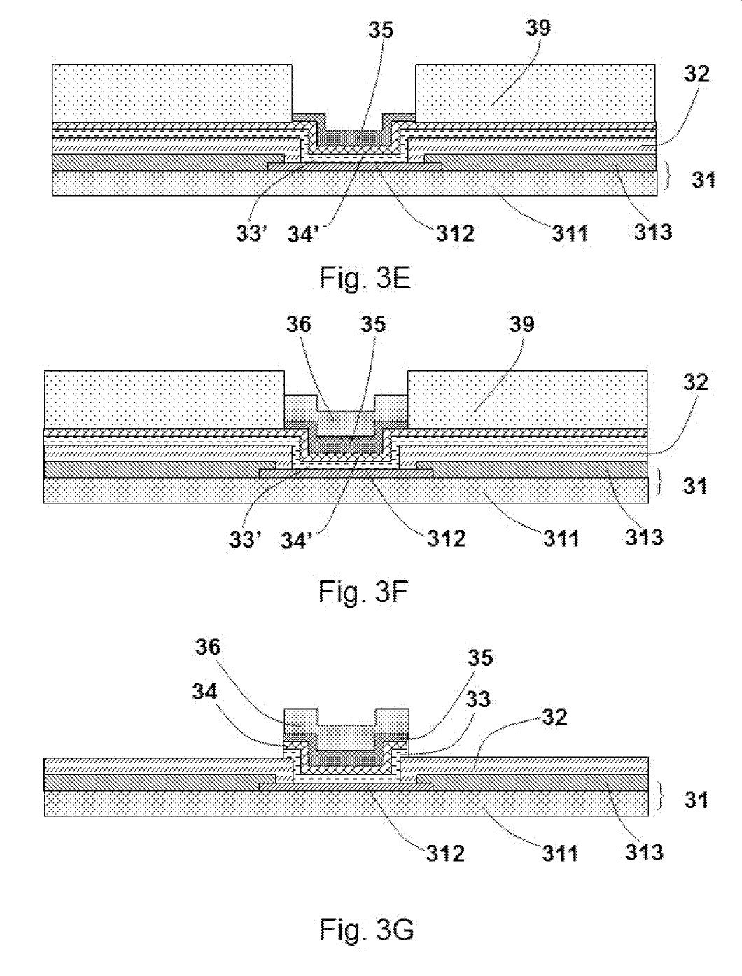

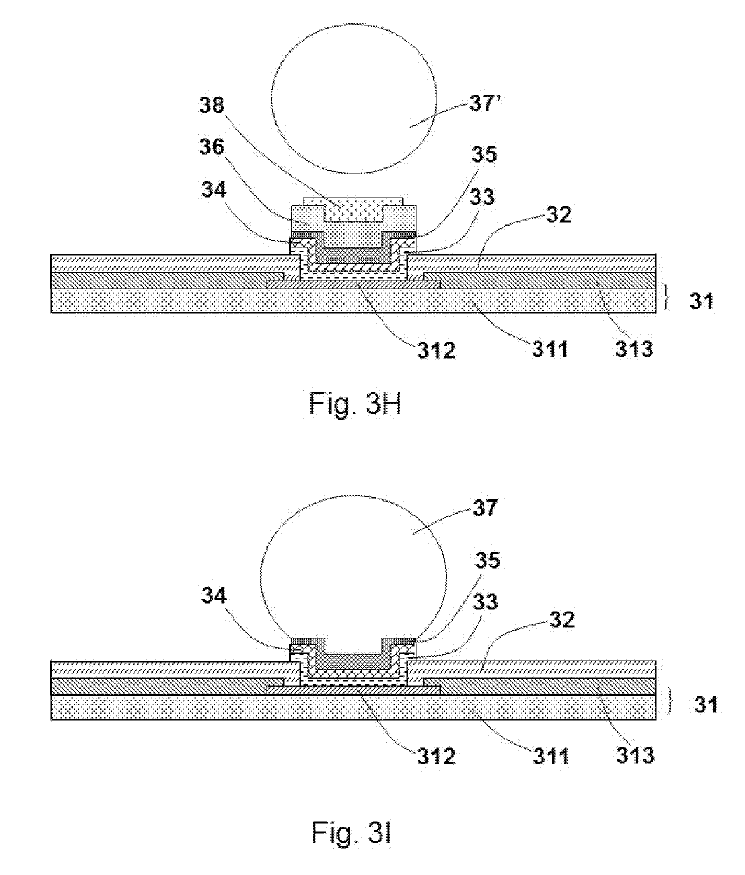

FIGS. 3A-3I show an embodiment of the present invention, illustrating the manufacturing steps of a WLCSP device. As shown in FIG. 3A, a chip 31 includes a semiconductor substrate 311, at least one bonding pad 312, and a first passivation layer 313. The bonding pad 312 is disposed on the active surface of the substrate 311, and the first passivation layer 313 protects the circuits (not shown) on the active surface. The first passivation layer 313 has at least one opening 314. The opening 314 exposes the bonding pad 312 so that internal wirings can be connected to external wirings.

On the first passivation layer 313, a second passivation layer 32 is further formed as shown in FIG. 3B. The second passivation layer 32 is deposited by spin coating or CVD (chemical vapor deposition), and its material may be any suitable passivation material such as silica, polyimide, BCB (benzocyclobutene), or PBO (polybenzoxazole). In this embodiment, the second passivation layer 32 overlays the border of the bonding pad 312, but the scope of the present invention is not limited to this example.

Referring to FIGS. 3C and 3D, a barrier layer 33′ and a seed layer 34′ are sequentially formed by sputtering or CVD. The barrier layer 33′ is for avoiding a rapid reaction between the bonding pad and the UBM in the following process, and the material of the barrier layer 33′ may include one or a combination of titanium, titanium nitride, an alloy of titanium and tungsten, tantalum, chromium, an alloy of chromium and copper, and tantalum nitride. The seed layer 34′ assists the crystal growth and the orientation of the UBM layer formed in the subsequent process, and its material is preferable to be the same as the material of the UBM layer.

The photoresist layer 39 is formed through a photolithography process, and then a UBM (under bump metallurgy) layer 35 is formed on the seed layer 34′, as shown in FIG. 3E. The material of the UBM layer 35 may be, but not limited to, Al/NiV/Cu, Ti/NiV/Cu, Ti/Cu/Ni, or etc. The photoresist layer 39 serves as a mask, and a pre-solder layer 36 is deposited on the UBM layer 35, as shown in FIG. 3F. The pre-solder layer 36 is preferably a metal or an alloy, which is capable of being melted and combined together with the later mounted bump. When the bump is solder, the pre-solder layer 36 preferably may be or include tin, an alloy of tin and lead, an alloy of tin and zinc, an alloy of tin and copper, or an alloy of tin, silver and copper.

Referring to FIG. 3G, the photoresist layer 39 is removed, and the portions of the barrier layer 33′ and the seed layer 34′ outside the pre-solder layer 36 are etched away. The barrier layer 33, the seed layer 34, the UBM layer 35, and the pre-solder layer 36, or some portions thereof, protruding on the second passive layer 32. Next, the flux 38 is coated on the UBM layer 35 through screen printing or any other suitable ways. The bump 37′ is mounted on the pre-solder layer 36 by a ball mounting step, as shown in FIG. 3H. The bump 37′ and the pre-solder 36 are melted and jointed together to form an I/O contact 37 by a reflow process. The size of the I/O contact 37 is larger than that of the bump 37′, as shown in 31. Thus, a large size I/O contact 37 is formed on the circuit board with a larger stand-off height. According to Coffin-Mansion equation, the reliability of the device is improved because of the larger stand-off height.

As described above, bumps with a larger size can increase the stand-off height, but there is likelihood that adjacent bumps might be adjoined together or a position shift of a bump might occur during the subsequent reflow process. In contrast to the prior art, the pre-solder layer 36 according to the present invention is fixed at its location, so it not only can increase the stand-off height, but also can avoid the risk of short-circuit because of adjoined adjacent bumps or position shift during the reflow process. Therefore, the reliability of the package device of the present application can be improved, in particular for electric devices having high number of I/O contacts with fine pitch. Furthermore, no additional photo mask is required, so the cost of the present device is not more than that of the conventional device. As an example to show the advantage of the present invention, in the current state of the art of a ball mounting process, if the pitch of the I/O contacts is 400 um, the maximum diameter of a solder ball is around 250 um, and the ball height after reflow is about 200 um (assuming the UBM layer having a diameter of 240 um). However, by the process of the present invention as described above, after a pre-solder layer with a thickness of 55 um is coated on the UBM layer, if a solder ball of the same size (diameter of 250 um) is still used, the height of the reflowed solder ball is about 220 um. That is, the stand-off height is increased by 10%; according to the estimation by the Coffin-Mansion equation, 10% increase of the stand-off height can increase the endurance cycle (representing the reliability) of such device by about 20%.

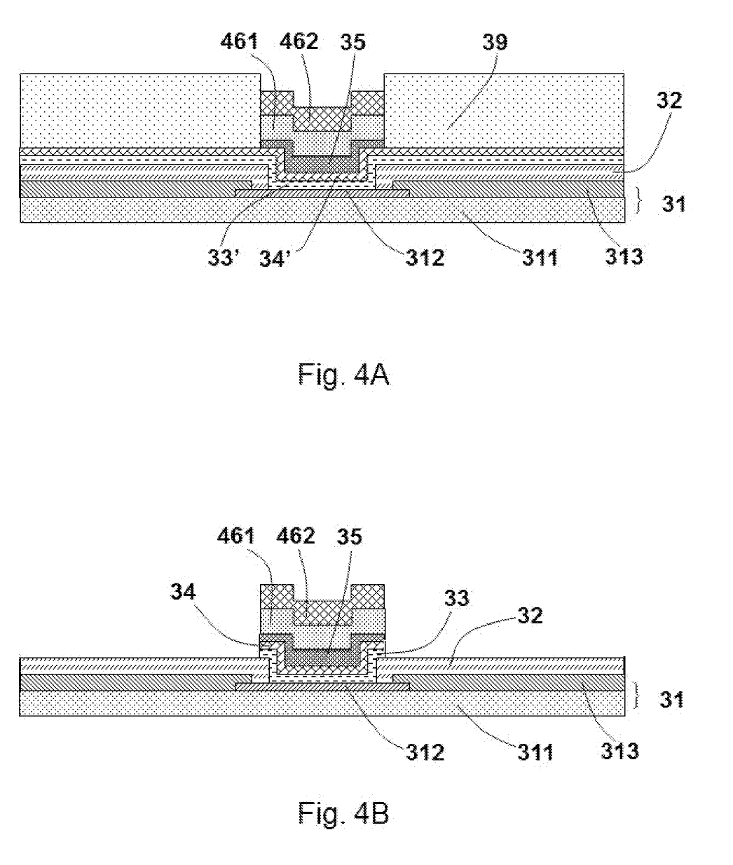

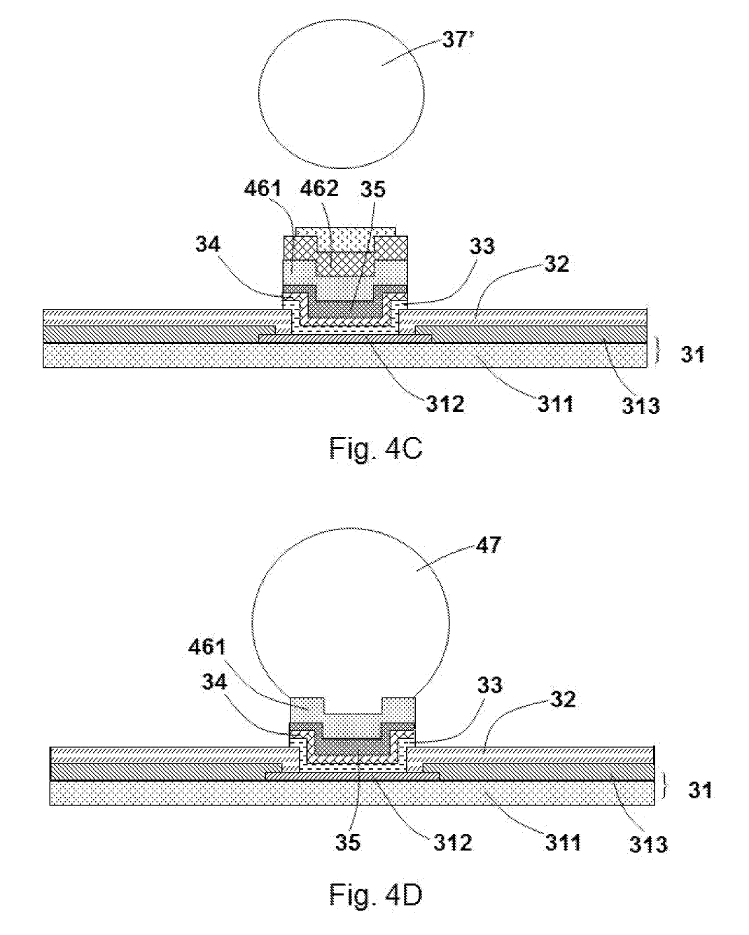

FIGS. 4A-4D show schematic diagrams of another embodiment of the present invention, illustrating the manufacturing steps of a WLCSP device. The manufacturing steps of the current embodiment follow FIG. 3E in the previous embodiment. That is, the manufacturing steps of the current embodiment start by FIGS. 3A-3E, and next FIG. 4A. Referring to FIG. 4A, with photoresist layer 39 still existing, a first pre-solder layer 461 with a higher melting point is deposited on the UBM layer 35, and then a second pre-solder 462 with a lower melting point than the first pre-solder layer 461 is deposited on the first pre-solder layer 461. The material of the second pre-solder layer 462 may include a metal or an alloy, which is capable of being melted and combined with the bumps mounted later; for example, it can use the same material of the pre-solder layer 36 of the previous embodiment. The material of the first pre-solder layer 461 may include solder with a high melting point, such as Sn/Au alloy or Sn/Zn alloy.

Referring to FIG. 4B, the photoresist layer 39 is removed, and the portions of the barrier layer 33′ and the seed layer 34′ outside the pre-solder layer 36 are etched away. The barrier layer 33, the seed layer 34, the UBM layer 35, the first pre-solder layer 461, and the second pre-solder layer 462, or some portions thereof, protruding on the second passive layer 32. Next, the flux 38 is coated on the UBM layer 35 through screen printing or any other suitable ways. The bump 37′ is mounted on the second pre-solder layer 462 by a ball mounting step, as shown in FIG. 4C. Referring to FIG. 4D, the bump 37′ and the second pre-solder 462 are melted and jointed together to form an I/O contact 47 through a reflow process, but the first pre-solder 461 with a higher melting point is not jointed together with them. The size of the I/O contact 47 is larger than that of the bump 37′, as shown in 4D. Thus, the stand-off height is effectively increased through the first pre-solder 461 with a higher melting point. According to the foregoing Coffin-Mansion equation, the reliability of the device is improved because of the increased stand-off height. However, the diameter of the solder ball is still the same or only slight larger, so it does not increase the risk for adjacent solder balls to adjoin together.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. Thus, the present invention should cover all such and other modifications and variations, which should be interpreted to fall within the scope of the following claims and their equivalents.

1.-13. (canceled)

14. A method for manufacturing a wafer level chip scale package device, comprising:
providing a chip having at least one bonding pad;
forming a UBM layer on the bonding pad;
forming a pre-solder layer on the UBM layer; and
melting and combining a bump and the pre-solder layer, whereby the pre-solder layer is melted and combined together with the bump to form one ball as an I/O contact.

15. The method for manufacturing a wafer level chip scale package device of claim 14, further comprising: forming a high melting point pre-solder layer between the UBM layer and the pre-solder layer, wherein the melting point of the high melting point pre-solder layer is higher than the melting point of the pre-solder layer.

16. The method for manufacturing a wafer level chip scale package device of claim 14, further comprising:
forming a barrier layer on the bonding pad; and
forming a seed layer between the barrier layer and the UBM layer.

17. The method for manufacturing a wafer level chip scale package device of claim 14, wherein the bump is a solder ball.

18. The method for manufacturing a wafer level chip scale package device of claim 17, wherein the material of the pre-solder layer includes one selected from the group consisting of tin, an alloy of tin and lead, an alloy of tin and zinc, an alloy of tin and copper, and an alloy of tin, silver and copper.

19. The method for manufacturing a wafer level chip scale package device of claim 17, wherein the material of the pre-solder layer includes a metal or an alloy, wherein the metal or alloy is capable of being melted and combined with the bump.

20. The method for manufacturing a wafer level chip scale package device of claim 14, wherein the pre-solder layer and the bump are combined together to form an I/O contact, and the size of the I/O contact is larger than the size of the bump.
